(19) United States
(12) Patent Application Publication
(10) Pub. No.: US 2022/0269971 A1
(43) Pub. Date: Aug. 25, 2022

(54) METHOD AND SYSTEM FOR GENERATING AND REGULATING LOCAL MAGNETIC FIELD VARIATIONS FOR SPIN QUBIT MANIPULATION USING MICRO-STRUCTURES IN INTEGRATED CIRCUITS

(71) Applicant: Qpiai India Private Limited, Bangalore (IN)

(72) Inventors: Umang Garg, New Delhi (IN); Pinakin Mansukhlal Padalia, Rajkot (IN); Amlan Mukherjee, Durgapur (IN); Nihal Sanjay Singh, Bangalore (IN); Nagendra Nagaraja, Bangalore (IN)

(21) Appl. No.: 17/680,234

(22) Filed: Feb. 24, 2022

(30) Foreign Application Priority Data
Feb. 24, 2021 (IN) 202141007818

(51) Int. Cl. G06N 10/40; B82Y 10/00

(52) U.S. Cl. CPC G06N 10/40; B82Y 10/00

(57) ABSTRACT

The embodiments herein provide a method and a system for generating and regulating local magnetic field variations required for spin qubit manipulation based on scalable quantum processors using micro-structures in integrated circuits. In an embodiment the system provides an adaptive and independent magnetic-field control to each qubit on a hardware substrate and comprises several micro/nano-scale current-carrying structures near a qubit for controlling and manipulating the qubit using the locally generated variable magnetic field, in-turn controlled by the tunable current flowing through these structures. The current-carrying structures in conjunction with fast current control provides fast switching/tuning of magnetic fields for rapid adiabatic passage control of one or more qubits simultaneously. The tenability of the qubits allows post-fabrication setting of adaptive magnetic field strengths and frequency separation of qubits thereby enabling the qubits to simultaneously realize their intended control signals without any added disturbance from neighboring qubits.

### BACKGROUND

### Technical Field

The embodiments herein are generally related to the field of quantum computing and quantum hardware design. The embodiments herein are more particularly related to system and method for spin qubits for generating and regulating local magnetic field variations required for spin qubit manipulation using micro-structures in integrated circuits.

### Description of the Related Art

Quantum computers have the potential to achieve exponential algorithmic speedups when compared to their classical counterparts. Intelligently formulated quantum algorithms leveraging superposition and entanglement phenomena hold great promise with respect to computational ease across a broad spectrum of fields and applications such as non-linear optimization, data management, material discovery, and cryptography. Given the recent developments in quantum computing hardware, several research groups (in both academia and industry) and startups have begun investing time, money, and human resources into the field of quantum computing with the hope of further advancing the technology to a stage wherein meaningful, and practically useful quantum algorithms can be efficiently run.

Typically, the quantum computers operate on the basic processing units called the quantum bits (also called Qubits). Contrary to classical bits, which can be in any one of the 2 states: 0 or 1, qubits can be in a superposition of these two states which are represented by the following ket notation: |0< and |1>. The state of a qubit is then represented by a wave function |ψ>=α|0>+β|1>, where α and β are complex numbers representing the probability amplitudes of qubit |ψ> being in the state |0> and state |1> respectively. From Bona's interpretation, the actual probability of |ψ> being in state |0> is given by a |α|² and that being in state |1> is given by |β|². An entire array of n such qubits can be superimposed with each other to generate a linear combination of 2ⁿ possible states where the computation can be done parallelly on all the 2ⁿ states in one go. The qubits can also be entangled to generate a highly correlated set of qubits allowing for more complex data correlation to happen at the hardware level. One such entangled state for two qubits is given as follows: |ϕ>=α|00>+β|11>. Here both the qubits are highly correlated in the sense that, if the measurement outcome of one of the qubits is |0>, then the other qubit is also in state |0> and vice versa if the measurement outcome for any one of the qubit is |1>.

The qubits can be implemented on various technology platforms such as nitrogen-vacancy (NV) centers in diamonds, superconducting transmons, semiconductor spin qubits, etc. Out of all implementations, the spin systems can be configured to form a well-defined two-level system that can be used for qubit implementation. Using an external static magnetic field B₀, it is possible to separate the degenerate spin states of a quantum particle (example electron) into two distinct levels form a ground state and an excited state of the spin. Only a single electron can occupy one of these states and with a defined spin state, thus forming a quantum bit with a ground state as |0> and the excited state as |1>[3].

Typically, any operation on a spin qubit is performed by applying microwave pulses of well-characterized frequency, phase, amplitude, and duration. The frequency used for qubit manipulation is linked to the Larmor frequency of this qubit, which in turn is defined by the local magnetic field B₀ by the following relation

$$Δ E = {hf}_{mw} = \frac{h {γ}_{e} {B}_{0}}{2 π} .$$

Here ΔE is the energy separation between the ground state and the excited state of the spin qubit, h is the Planck's constant, f_{mw} is the Larmor frequency/microwave frequency required for qubit manipulation,

$$\frac{{γ}_{e}}{2 π}$$

the gyromagnetic ratio for electrons (˜28 GHz/T) and B₀ is the local magnetic field near the qubit. This magnetic field is a combination of the dominant applied static magnetic field and the fluctuating magnetic fields generated by the surrounding nuclear spins and other phenomena. The current state of the art spin qubits in semiconductor materials are very few (<10) and operate around 10s of GHz, requiring magnetic fields of the order of ˜1 T.

While scaling up this architecture with multiple qubits, it is required that the hardware can control multiple qubits without disturbing the idle qubits in the vicinity. However, the qubits are extremely sensitive to the environment and any operation on one qubit will result in a spurious operation on a nearby qubit if they operate at the same Larmor frequency. Thus, to operate with millions of qubits, one way is to generate frequency spacing between these qubits allowing for the Frequency Division Multiplexing (FDM) scheme, thereby reducing the crosstalk between the qubits and allowing for coherent control of multiple qubits with required fidelity. However, the FDM scheme is infeasible for quantum algorithms due to the need for parallelization of control operations. Some groups also use Time-division multiplexing (TDM) on circuitry common to all qubits (wherein one cannot simultaneously address multiple qubits), or multiple instances of control circuitry in an attempt to address a few qubits simultaneously. However, the TDM results in redundant hardware and increased power consumption. Also, TDM based schemes are further impractical due to the extremely short coherence time of currently developed qubits. In order to maximize the performance of a quantum computing machine, most often FDM solutions are used with TDM as an optional choice. But with the large hardware requirements posed by present architectures supporting FDM, it becomes increasingly difficult to scale this hardware, especially concerning the quantum read and write control circuits.

Further, one of the standard ways for generating the required frequency spacing in Larmor frequency for different qubits, is by having a static magnetic field gradient. Using a static magnetic field gradient is not feasible for spin qubits in silicon for example, due to their very small size (˜100 nm) allowing for a very tiny gradient in a magnetic field. Hence, the frequency spacing is not high enough for well-defined manipulation. Currently, the quantum hardware development groups attempting to tackle this problem utilize cobalt-based microscopic-magnets to generate precise magnetic fields near the qubits. For example, a 250 nm thick cobalt micro-magnet deposited on top of the accumulation gate is typically used in order to induce a stray magnetic field around their semiconductor qubit. However, the above approach is more challenging and inconvenient in standard fabrication processes, and also doesn't allow any tunability in the magnetic field post-fabrication as it contains a constant ever-present magnetic field.

Hence, there is need for a system and a method for generating and regulating local magnetic field variations required for spin qubit manipulation that provides individual tunability of qubits and simultaneous control, while also paving the way for the integration of millions of more qubits due to with lower overall power consumption.

The above-mentioned shortcomings, disadvantages and problems are addressed herein, and which will be understood by reading and studying the following specification.

### Objectives of the Embodiments Herein

The primary object of the embodiments herein is to provide a system and method for generating and regulating local magnetic field variations required for spin qubit manipulation using scalable micro-structures in integrated circuits.

Another object of the embodiments herein is to provide a system comprising quantum processors for generating local magnetic field variations required for spin qubit manipulation using micro-structures in integrated circuits, that facilitate frequency-division multiplexing (FDM) of signals required to control semiconductor qubits by utilizing standard fabrication processes.

Yet another object of the embodiments herein is to provide a method and a system for generating and regulating local magnetic field variations required for spin qubit manipulation using scalable quantum processors and micro-structures in integrated circuits, that reduces an overall chip area which is paramount for practical and scalable quantum processor design.

Yet another object of the embodiments herein is to provide a system and a method for generating and regulating local magnetic field variations required for spin qubit manipulation using scalable quantum processors and micro-structures in integrated circuits, that tackles the challenge of generating differing magnetic fields for various qubits efficiently while additionally allowing the tunability of parameters, including the qubit frequencies and their frequency-separation from one another.

Yet another object of the embodiments herein is to provide a method and a system for generating and regulating local magnetic field variations required for spin qubit manipulation using scalable quantum processors and micro-structures in integrated circuit, that reduces an overall power consumption by rendering dedicated qubit-specific control hardware obsolete.

Yet another object of the embodiments herein is to provide a method and a system for generating and regulating local magnetic field variations required for spin qubit manipulation using scalable quantum processors and micro-structures in integrated circuits, that archives the need for multiple redundant control hardware instances while also enabling the essential parallelized control of different qubits.

Yet another object of the embodiments herein is to provide a method and a system for generating and regulating local magnetic field variations required for spin qubit manipulation using scalable quantum processors and micro-structures in integrated circuits, that provides an architectural modification to standard semiconductor qubits to facilitate their individual tunability and simultaneous control, while also paving the way for the integration of thousands and even millions of more qubits due to its ability to multiplex hardware and lower overall power consumption.

Yet another object of the embodiments herein is to provide a method and a system for generating and regulating local magnetic field variations required for spin qubit manipulation using scalable quantum processors and micro-structures in integrated circuits, that allows a post-fabrication setting of adaptive magnetic field strengths and frequency separation of qubits. The qubits are hence able to simultaneously realize their intended control signals without any added disturbance from neighboring qubits.

Yet another object of the embodiments herein is to provide a method and a system for generating and regulating local magnetic field variations required for spin qubit manipulation using scalable quantum processors and micro-structures in integrated circuits, that can easily support both electron spin resonance (ESR) and electric dipole spin resonance (EDSR) control techniques, as per the algorithmic requirements, with an added possibility of realizing hybrid switching schemes to turn the local magnetic fields off and on as per the requirements

These and other objects and advantages of the present invention will become readily apparent from the following detailed description taken in conjunction with the accompanying drawings.

### SUMMARY

The following details present a simplified summary of the embodiments herein to provide a basic understanding of the several aspects of the embodiments herein. This summary is not an extensive overview of the embodiments herein. It is not intended to identify key/critical elements of the embodiments herein or to delineate the scope of the embodiments herein. Its sole purpose is to present the concepts of the embodiments herein in a simplified form as a prelude to the more detailed description that is presented later.

The other objects and advantages of the embodiments herein will become readily apparent from the following description taken in conjunction with the accompanying drawings. It should be understood, however, that the following descriptions, while indicating preferred embodiments and numerous specific details thereof, are given by way of illustration and not of limitation. Many changes and modifications may be made within the scope of the embodiments herein without departing from the spirit thereof, and the embodiments herein include all such modifications.

The various embodiments herein provide a system and a method for generating and regulating local magnetic field variations required for spin qubit manipulation using scalable quantum processors and micro-structures in integrated circuits.

The various embodiments herein provide, a system for generating and regulating local magnetic field variations required for spin qubit manipulation using scalable quantum processors and micro-structures in integrated circuits is provided. The system comprises a circuit configured to provide an adaptive and independent magnetic-field control to each qubit on a hardware substrate. The hardware substrate comprises silicon substrate. The circuit comprises a plurality of micro/nano-scale current-carrying structures in the vicinity of a qubit for controlling and manipulating the qubit using the locally generated variable magnetic field, in-turn controlled by the tunable current flowing through these structures. The current-carrying structures in conjunction with fast current control is configured to provide fast switching/tuning of magnetic fields enabling rapid adiabatic passage control or tunability of one or more qubits simultaneously. The tunability of the one or more qubits allows post-fabrication setting of adaptive magnetic field strengths and frequency separation of the one or more qubits thereby enabling the one or more qubits to simultaneously realize their intended control signals without any added disturbance from neighboring one or more qubits.

According to one embodiment herein, the system provides an architectural modification to standard semiconductor qubits that facilitate their individual tunability and simultaneous control, while also paving the way for the integration of millions of one or more qubits due to its ability to multiplex hardware and lower overall power consumption. The tunability of the qubits allows post-fabrication setting of adaptive magnetic field strengths and frequency separation of one or more qubits. This enables the qubits to simultaneously realize their intended control signals without any added disturbance from neighboring qubits.

According to one embodiment herein; the system can easily support both electron spin resonance (ESR) and electric dipole spin resonance (EDSR) control techniques, as per the algorithmic requirements, with an added possibility of realizing hybrid switching schemes to turn the local magnetic fields off and on as per the requirements. The system of the present technology operates based on the fact that any current-carrying wire proportionately induces a magnetic field in its periphery (Oersted's Law), based on this phenomenon the system is designed to include micro/nano-scale superconducting current-carrying structures in the qubit's vicinity for precisely controlling and manipulating them using the locally generated variable magnetic field, in-turn controlled by the tunable current flowing through these structures. Such current-carrying structures in conjunction with fast current control can provide fast switching/tuning of magnetic fields enabling rapid adiabatic passage control of single spin qubits or multiple qubits at the same time.

According to one embodiment herein, the plurality of micro/nano-scale current carrying structures comprises single current carrying loop or multiple current carrying loop. In addition, the plurality of micro/nano-scale current carrying structures can be made vertical or horizontal or a combination of both, allowing for flexible control of local magnetic fields or generation of a local magnetic field gradient for the qubits thus forming a vector magnet. The plurality of micro/nano-scale current carrying structures can be superconducting or normal metal structures based on the requirements of the local magnetic field strength and the operational temperature for the qubits. Lower temperatures facilitate superconducting micro-structures with higher magnetic field densities. Furthermore, the plurality of micro/nano-scale current carrying structures in the form of normal metal loops or superconducting loops can be split into two or more loops.

According to one embodiment herein, the qubit utilized is semiconductor-based spin qubits are considered here for the descriptive explanation of the present technology. Any system with two different well-defined quantum-mechanical levels qualifies as a qubit. The electrons moving through transistors fabricated in complementary metal oxide semiconductor (CMOS) technology under proper temperature and biasing conditions can be used as a qubit. Specifically, upon experiencing an external static field, the spin of the electron splits into two discrete spin-up and spin-down states, thus forming qubits that enable quantum computing. The split energy of the magnetic two states also governs the precession frequency (called Larmor frequency) for the qubit under study.

According to one embodiment herein, a method of co-integrating multiple qubit structures with local magnetic field generating micro-structures for defining qubit operating frequencies spin qubits, is disclosed. The method includes generating user-controlled local magnetic field in integrated circuits for multiple qubit structures using plurality of micro/nano-scale current-carrying structures. The method further includes generating user-defined magnetic field direction with varying placement and orientation of current-carrying micro-structures forming a vector magnet. The method further includes applying well defined magnetic fields to the multiple qubit structures by varying the current levels and the number of turns associated with the plurality of micro/nano-scale current-carrying structure loops.

According to one embodiment herein, the placement of the plurality of micro/nano-scale current carrying structures can be varied, forming 2D/3D structures of different geometrical shapes and not just squares as permitted by the fabricating facilities. Furthermore, the orientation of the plurality of micro/nano-scale current carrying structures can be vertical orientation of current carrying loop or horizontal orientation of current carrying loop or a combination of both, allowing for flexible control of local magnetic fields or generation of a local magnetic field gradient for the qubits thus forming a vector magnet. Moreover, the combination of both or hybrid structure can also be implemented which combines the vertical and horizontal orientation of current carrying loops to form an arbitrary magnetic field direction for local magnetic field variations in essence forming a vector magnet whose field strength and the direction is controlled by the user.

According to one embodiment herein, the plurality of micro/nano-scale current-carrying structures can be in-plane of the multiple qubit structures as allowed by the fabrication processes forming the required magnetic field instead of placing them at a vertical displacement from the multiple qubit structures.

According to one embodiment herein, multiple qubit structures can be placed around a single current carrying loop at different locations allowing to make use of the different magnetic field orientations and strengths surrounding the single current carrying loop. Such an embodiment makes use of the existing gradients of the single current carrying loop thereby further reducing the required hardware for generating well-defined local magnetic fields per qubit structure.

Therefore, the system and method provides an architectural modification to the standard semiconductor qubits that facilitate their individual tunability and simultaneous control, while also paving the way for the integration of millions of more qubits due to its ability to multiplex hardware and lower overall power consumption. Further, the system enables tunability of the qubits that enables post-fabrication setting of adaptive magnetic field strengths and frequency separation of qubits that further enables the qubits to simultaneously realize their intended control signals without any added disturbance from neighboring qubits.

These and other aspects of the embodiments herein will be better appreciated and understood when considered in conjunction with the following description and the accompanying drawings. It should be understood, however, that the following descriptions, while indicating the preferred embodiments and numerous specific details thereof, are given by way of an illustration and not of a limitation. Many changes and modifications may be made within the scope of the embodiments herein without departing from the spirit thereof, and the embodiments herein include all such modifications.

### BRIEF DESCRIPTION OF THE DRAWINGS

The other objects, features, and advantages will occur to those skilled in the art from the following description of the preferred embodiment and the accompanying drawings in which:

FIG. 1 depicts a system for generating and regulating local magnetic field variations for spin qubit manipulation using scalable quantum processors and micro-structures in integrated circuits, according to an embodiment herein.

FIG. 2 depicts a system for generating and regulating local magnetic field variations for spin qubit manipulation using scalable quantum processors and micro-structures in integrated circuits, according to an embodiment herein.

FIG. 3 depicts a system for generating and regulating local magnetic field variations for spin qubit manipulation using scalable quantum processors and micro-structures in integrated circuits, according to an embodiment herein.

FIG. 4 depicts a system for generating and regulating local magnetic field variations for spin qubit manipulation using scalable quantum processors and micro-structures in integrated circuits, according to an embodiment herein.

FIG. 5 depicts a system for generating and regulating local magnetic field variations for spin qubit manipulation using scalable quantum processors and micro-structures in integrated circuits, according to an embodiment herein.

FIG. 6 depicts a system for generating and regulating local magnetic field variations for spin qubit manipulation using scalable quantum processors and micro-structures in integrated circuits, according to an embodiment herein.

FIG. 7 illustrates a flow diagram depicting a method of co-integrating the qubit structures with local magnetic field generating micro-structures for defining the qubit operating frequencies in the case of spin qubits, according to an embodiment herein.

Although the specific features of the embodiments herein are shown in some drawings and not in others. This is done for convenience only as each feature may be combined with any or all of the other features in accordance with the embodiments herein.

### DETAILED DESCRIPTION OF THE EMBODIMENTS HEREIN

In the following detailed description, a reference is made to the accompanying drawings that form a part hereof, and in which the specific embodiments that may be practiced is shown by way of illustration. These embodiments are described in sufficient detail to enable those skilled in the art to practice the embodiments and it is to be understood that other changes may be made without departing from the scope of the embodiments. The following detailed description is therefore not to be taken in a limiting sense.

The various embodiments herein provide a system and a method for generating and regulating local magnetic field variations required for spin qubit manipulation using scalable quantum processors and micro-structures in integrated circuits.

The various embodiments herein provide, a system for generating and regulating local magnetic field variations required for spin qubit manipulation using scalable quantum processors and micro-structures in integrated circuits is provided. The system comprises a circuit configured to provide an adaptive and independent magnetic-field control to each qubit on a hardware substrate. The hardware substrate comprises silicon substrate. The circuit comprises a plurality of micro/nano-scale current-carrying structures in the vicinity of a qubit for controlling and manipulating the qubit using the locally generated variable magnetic field, in-turn controlled by the tunable current flowing through these structures. The current-carrying structures in conjunction with fast current control is configured to provide fast switching/tuning of magnetic fields enabling rapid adiabatic passage control or tunability of one or more qubits simultaneously. The tunability of the one or more qubits allows post-fabrication setting of adaptive magnetic field strengths and frequency separation of the one or more qubits thereby enabling the one or more qubits to simultaneously realize their intended control signals without any added disturbance from neighboring one or more qubits.

According to one embodiment herein, the system provides an architectural modification to standard semiconductor qubits that facilitate their individual tunability and simultaneous control, while also paving the way for the integration of millions of one or more qubits due to its ability to multiplex hardware and lower overall power consumption. The tunability of the qubits allows post-fabrication setting of adaptive magnetic field strengths and frequency separation of one or more qubits. This enables the qubits to simultaneously realize their intended control signals without any added disturbance from neighboring qubits.

According to one embodiment herein, the system can easily support both electron spin resonance (ESR) and electric dipole spin resonance (EDSR) control techniques, as per the algorithmic requirements, with an added possibility of realizing hybrid switching schemes to turn the local magnetic fields off and on as per the requirements. The system of the present technology operates based on the fact that any current-carrying wire proportionately induces a magnetic field in its periphery (Oersted's Law), based on this phenomenon the system is designed to include micro/nano-scale superconducting current-carrying structures in the qubit's vicinity for precisely controlling and manipulating them using the locally generated variable magnetic field, in-turn controlled by the tunable current flowing through these structures. Such current-carrying structures in conjunction with fast current control can provide fast switching/tuning of magnetic fields enabling rapid adiabatic passage control of single spin qubits or multiple qubits at the same time.

According to one embodiment herein, the plurality of micro/nano-scale current carrying structures comprises single current carrying loop or multiple current carrying loop. In addition, the plurality of micro/nano-scale current carrying structures can be made vertical or horizontal or a combination of both, allowing for flexible control of local magnetic fields or generation of a local magnetic field gradient for the qubits thus forming a vector magnet. The plurality of micro/nano-scale current carrying structures can be superconducting or normal metal structures based on the requirements of the local magnetic field strength and the operational temperature for the qubits. Lower temperatures facilitate superconducting micro-structures with higher magnetic field densities. Furthermore, the plurality of micro/nano-scale current carrying structures in the form of normal metal loops or superconducting loops can be split into two or more loops.

According to one embodiment herein, the qubit utilized is semiconductor-based spin qubits are considered here for the descriptive explanation of the present technology. Any system with two different well-defined quantum-mechanical levels qualifies as a qubit. The electrons moving through transistors fabricated in complementary metal oxide semiconductor (CMOS) technology under proper temperature and biasing conditions can be used as a qubit. Specifically, upon experiencing an external static field, the spin of the electron splits into two discrete spin-up and spin-down states, thus forming qubits that enable quantum computing. The split energy of the magnetic two states also governs the precession frequency (called Larmor frequency) for the qubit under study.

According to one embodiment herein, a method of co-integrating multiple qubit structures with local magnetic field generating micro-structures for defining qubit operating frequencies spin qubits, is disclosed. The method includes generating user-controlled local magnetic field in integrated circuits for multiple qubit structures using plurality of micro/nano-scale current-carrying structures. The method further includes generating user-defined magnetic field direction with varying placement and orientation of current-carrying micro-structures forming a vector magnet. The method further includes applying well defined magnetic fields to the multiple qubit structures by varying the current levels and the number of turns associated with the plurality of micro/nano-scale current-carrying structure loops.

According to one embodiment herein, the placement of the plurality of micro/nano-scale current carrying structures can be varied, forming 2D/3D structures of different geometrical shapes and not just squares as permitted by the fabricating facilities. Furthermore, the orientation of the plurality of micro/nano-scale current carrying structures can be vertical orientation of current carrying loop or horizontal orientation of current carrying loop or a combination of both, allowing for flexible control of local magnetic fields or generation of a local magnetic field gradient for the qubits thus forming a vector magnet. Moreover, the combination of both or hybrid structure can also be implemented which combines the vertical and horizontal orientation of current carrying loops to form an arbitrary magnetic field direction for local magnetic field variations in essence forming a vector magnet whose field strength and the direction is controlled by the user.

According to one embodiment herein, the plurality of micro/nano-scale current-carrying structures can be in-plane of the multiple qubit structures as allowed by the fabrication processes forming the required magnetic field instead of placing them at a vertical displacement from the multiple qubit structures.

According to one embodiment herein, multiple qubit structures can be placed around a single current carrying loop at different locations allowing to make use of the different magnetic field orientations and strengths surrounding the single current carrying loop. Such an embodiment makes use of the existing gradients of the single current carrying loop thereby further reducing the required hardware for generating well-defined local magnetic fields per qubit structure.

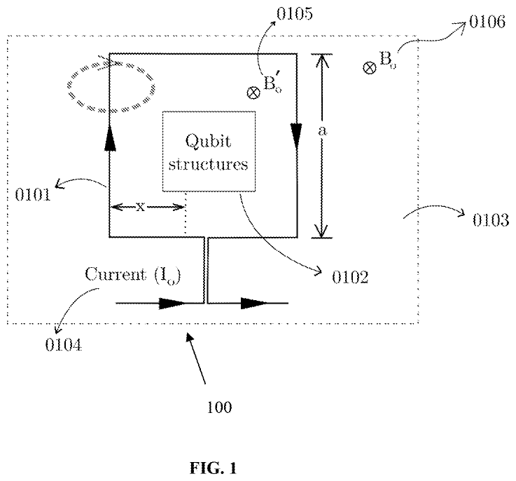

According to one embodiment herein, FIG. 1 depicts a system 100 for generating local magnetic field variations for spin qubit manipulation using scalable quantum processors and micro-structures in integrated circuit. FIG. 1 illustrates a system 100 comprising metal-wire micro-structures 101 that are introduced around each qubit structure 102 that represents qubits on a silicon substrate 103. As known in the art, any wire carrying current induces a proportionate amount of magnetic field in its periphery (Oersted's Law), the micro-structure 101 (loop in this case) carrying a current (Io) 0104 will have an associated magnetic field (Bo′) 105 at the site of an electron serving as the spin qubit within the qubit structure 102. In this particular embodiment, which includes the micro-structure in the form of a loop circuit, the local magnetic field (Bo′) 105 enhances the static magnetic field (Bo) 106. In a different embodiment of the invention, the current 104 in the loop can traverse in the opposite direction to decrease the effective local magnetic field at the qubit structure 102. The static magnetic field (B0) 106 induces an equal magnetic field for each qubit in the circuit.

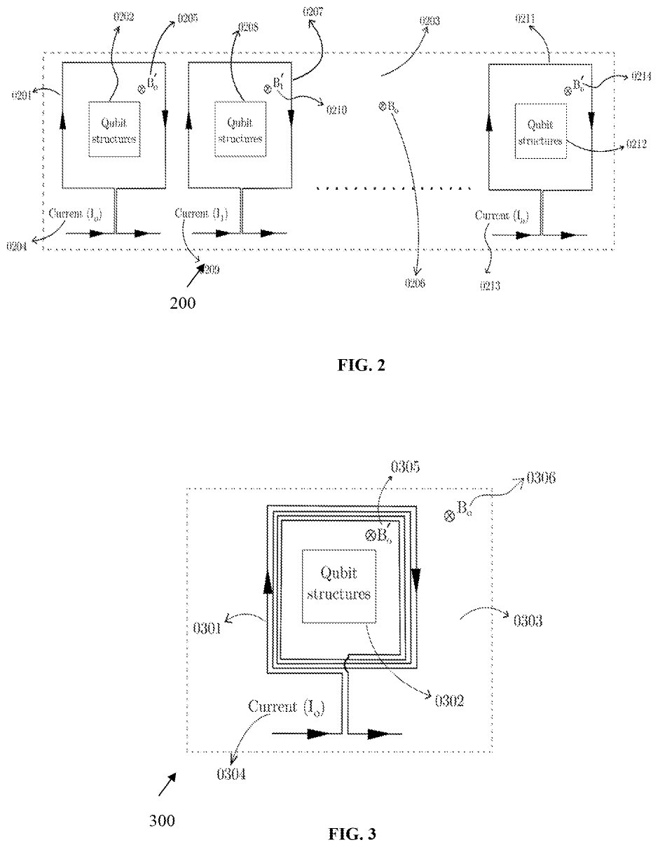

Furthermore, the micro-structures in form of metal loops 101 can be superconducting in order to generate sustaining magnetic fields with negligible heat generation to accommodate the entire structure at millikelvin (mK) stages in the dilution refrigerator using qubit structures 102 at around 20 mK temperatures. Additionally, in order to perform computations using the spin qubits with no added hardware costs, a frequency division multiplexing (FDM) scheme becomes a necessity. This can be either implemented using either the ESR or EDSR technique. ESR involves a microwave line that carries modulated current signals which encode operation information for each qubit at their designated Larmor frequency. EDSR on the other hand, involves directly pulsing the gates of the transistors with a similarly modulated voltage signal. However, in order to enable FDM and operate two independent qubits simultaneously, it is necessary to have a minimum separation between different qubits' Larmor frequencies, so that there is no unwanted interference to the concerned entity. The system of the present technology implemented to have a minimum separation between different qubits' Larmor frequencies is described along with FIG. 2.

According to one embodiment herein, FIG. 2 depicts a system 200 for generating local magnetic field variations required for spin qubit manipulation using scalable quantum processors and micro-structures in integrated circuits. The FIG. 2 illustrates a system 200 comprising multiple micro-structures 0201, 0207, 0211 in form of loops of current-carrying wires being placed side by side with varying currents 0204, 0209, 0213 to implement different magnetic fields for the qubit structures in the center of each loop 0205, 0210, 0214 respectively. This allows for different Larmor frequencies for the qubit structures 0202, 0208, 0212. The qubit structures can be a single physical qubit or a logical qubit consisting of multiple physical qubits. The entire circuit of the system 200 is on a common substrate 203 and is exposed to a common static magnetic field in the background (Bo) 206.

According to one embodiment herein, the circuit includes micro-structures with multiple current carrying loops. FIG. 3 depicts a system 300 for generating local magnetic field variations required for spin qubit manipulation using scalable quantum processors and micro-structures in integrated circuits. The FIG. 3 illustrates a system 300 comprising micro-structures with multiple current carrying loops (superconducting or otherwise) 0301 allowing for low current usage for the generation of the same amount of magnetic fields (B0′) 0305 in accordance to the proportionality: B0′∝n*I, where n is the number of loops in a micro-structure and I is the current flowing in the loops. The system 300 further includes a substrate 0303 housing the qubit structures 0302 with micro-structure as multiple current carrying loops 0301 generating a local magnetic field (B0′) 0305. The multiple current carrying loops can be in a single plane with the same metal layer forming a spiral loop or they can also be implemented as multiple loops spanning across multiple metal layers (M1, M2, and so on up to Mn) as in the case of the metal layers provided in the standard CMOS fabrication process.

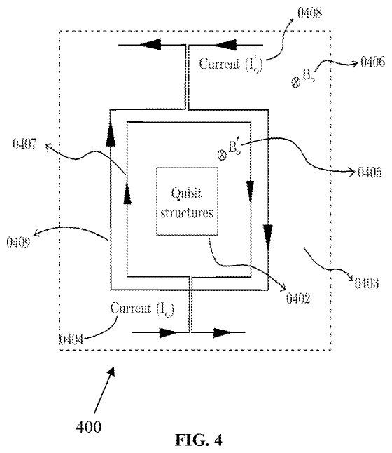

According to one embodiment herein, FIG. 4 depicts a system 400 for generating local magnetic field variations required for spin qubit manipulation using scalable quantum processors and micro-structures in integrated circuits. FIG. 4 illustrates a system 400 includes micro-structures in the form of metal loops (or superconducting loops) that be split into two or more loops (409 and 407) as illustrated in FIG. 4. The two or more loops includes for example a first loop 409 and a second loop 407 as shown in FIG. 4. Each of the first loop 409 and the second loop 407 have their own individual current control circuits 404 and 408 respectively allowing for a controlled magnetic field generation. The loops 409 and 407 can be used for coarse and fine local magnetic field adjustments over the qubit structures 402 or a binary/unitary/hybrid control over the magnetic field using only a finite number of current sources as opposed to continuously varying currents required for generating the magnetic fields. In yet another embodiment of the invention, the loops can be broken down into independent lines carrying individual currents and forming a well-defined magnetic field in the space between the independent current carrying lines.

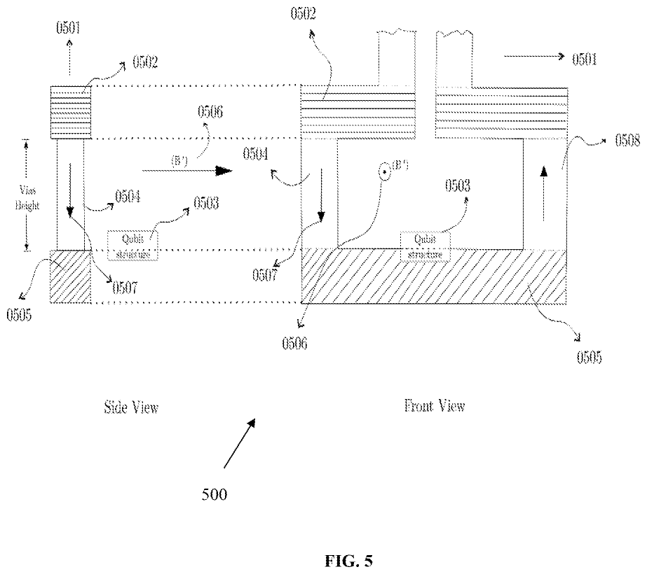

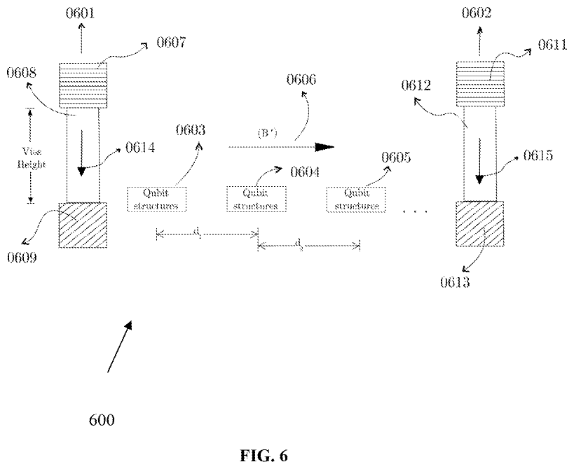

According to one embodiment herein, FIG. 5 depicts a side view and a front view of a system 500 for generating local magnetic field variations required for spin qubit manipulation using scalable quantum processors and micro-structures in integrated circuits. FIG. 5 illustrates a system 500 includes a different placement and construction of the micro-structure in form of a current carrying loop. The system 500 includes a vertical orientation of the loop (vertical loop) formed by making use of multiple metal layers connected by vias in the standard fabrication process. A standard fabrication process is taken as an example, however any fabrication form allowing for 3D formation of such micro-structures can be used. In the side view of the vertical loop, the vertical placement of the loop 501 is visible with metal layers 502, 0505 and the vias 504, 0508 forming the loop structure. The current 507 generates a local magnetic field 0506 which is in plane of the qubit structure 503. The front view of the vertical loop depicts the qubit structure 503 behind the vertical loop 501.

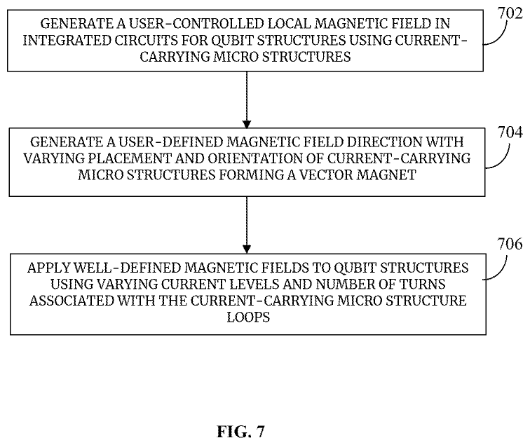

According to one embodiment herein, FIG. 6 depicts a system 600 for generating local magnetic field variations required for spin qubit manipulation using scalable quantum processors and micro-structures in integrated circuits. More particularly, FIG. 6 depicts a side view of a vertical micro-structure in form of a current-carrying loop (0601, 0602) of the system 600. The system 600 includes two different metal layers (0607, 0609) and (0611, 0613) required for the formation of such a structure. The vias (0608, 0612) making the electrical connection, forms the two sides of the loop forming a vertical loop structure. In general, the vias can span between two consecutive metal layers or even multiple metal layers for defining the loop area. The vertical loops can be separated by a finite distance having multiple qubit structures in between allowing a well-defined gradient in the lateral magnetic field as illustrated in FIG. 6. The structure named N 0601 and structure namely N+1 0602 are separated horizontally by a distance d forming a lateral magnetic field in the space in between the structures. Multiple qubit structures (0603, 0604, 0605) are placed at a finite interval (d1, d2) in between the vertical loop structures (0601, 0602). The current in the separate loops can be controlled individually to maintain either a constant magnetic field in the space housing the quantum structures or forming a well-defined magnetic field gradient by allowing for different currents in structure N (0614) and structure N+1 (0615).

According to one embodiment herein, a hybrid structure can also be implemented which combines the vertical and horizontal current carrying loops to form an arbitrary magnetic field direction for local magnetic field variations in essence forming a vector magnet whose field strength and the direction is controlled by the user. Furthermore, the current-carrying loop can be in-plane of the quantum structures as allowed by the fabrication processes forming the required magnetic field instead of placing them at a vertical displacement from the quantum structures as illustrated in the examples.

According to one embodiment herein, multiple qubit structures can be placed around a singular loop structure at different locations allowing to make use of the different magnetic field orientations and strengths surrounding the loop. Such an embodiment makes use of the existing gradients from a single loop thereby further reducing the required hardware for generating well-defined local magnetic fields per qubit structure.

Hence, embodiments herein, can make use of different semiconductor materials used for manufacturing spin qubits and are not limited to spin or CMOS processes as described as an example. Moreover, the fabricated devices can be custom made or designed using standard commercial fabrication facilities. The scope of the invention is not limited to the fabrication method adopted or the type of material used for current-carrying micro-structures. The placement of the micro-structures can be varied, forming 2D/3D structures of different geometrical shapes and not just squares as permitted by the fabricating facilities and as illustrated in the current examples. Moreover, it is also possible to use different materials that are highly resistive at nominal temperatures but can go superconducting at low temperatures allowing the formation of current-carrying micro-structures and generation of magnetic fields. In some embodiments the orientation and placement of the micro-structures that constitute the system of the present technology can be changed to allow for local control of magnetic field vectors. A method co-integrating the qubit structures for defining the qubit operating frequencies is described along with FIG. 7.

According to one embodiment herein, FIG. 7 illustrates a flow diagram depicting a method of co-integrating the qubit structures with local magnetic field generating micro-structures for defining the qubit operating frequencies in the case of spin qubits. At step 702, user-controlled local magnetic field is generated in integrated circuits for qubit structures using current-carrying micro-structures. At step 704, user-defined magnetic field direction with varying placements and orientations of current carrying micro-structures forming a vector magnet is generated. At 706, a well-defined magnetic field is applied to qubit structures using varying current levels and number of turns associated with the current carrying micro-structure loops.

Although the embodiments herein are described with various specific embodiments, it will be obvious for a person skilled in the art to practice the embodiments herein with modifications.

The system for generating and regulating local magnetic field variations for spin qubit manipulation using scalable quantum processors and micro-structures in integrated circuits disclosed in the embodiments herein have several exceptional advantages. The system and method that provides an architectural modification to standard semiconductor qubits that facilitate their individual tunability and simultaneous control, while also paving the way for the integration of millions of more qubits due to its ability to multiplex hardware and lower overall power consumption. Further, the system enables tunability of the qubits that enables post-fabrication setting of adaptive magnetic field strengths and frequency separation of qubits that further enables the qubits to simultaneously realize their intended control signals without any added disturbance from neighboring qubits. Moreover, the present system can easily support both electron spin resonance (ESR) and electric dipole spin resonance (EDSR) control techniques, as per the algorithmic requirements, with an added possibility of realizing hybrid switching schemes to turn the local magnetic fields off and on as per the requirements. Furthermore, the system of the present technology operates based on the fact that any current-carrying wire proportionately induces a magnetic field in its periphery (Oersted's Law), based on this phenomenon the system is designed to include micro/nano-scale superconducting current-carrying structures in the vicinity of qubit for precisely controlling and manipulating them using the locally generated variable magnetic field, in-turn controlled by the tunable current flowing through these structures. Such current-carrying structures in conjunction with fast current control can provide fast switching/tuning of magnetic fields enabling rapid adiabatic passage control of single spin qubits or on multiple qubits at the same time.

The embodiments herein include micro-structures that can be made vertical or horizontal or a combination of both, allowing for flexible control of local magnetic fields or generation of a local magnetic field gradient for the qubits thus forming a vector magnet. The micro-structures can be superconducting or normal metal structures based on the requirements of the local magnetic field strength and the operational temperature for the qubits. Lower temperatures facilitate superconducting micro-structures with higher magnetic field densities.

The foregoing description of the specific embodiments will so fully reveal the general nature of the embodiments herein that others can, by applying current knowledge, readily modify and/or adapt for various applications such as specific embodiments without departing from the generic concept, and, therefore, such adaptations and modifications should and are intended to be comprehended within the meaning and range of equivalents of the disclosed embodiments.

It is to be understood that the phraseology or terminology employed herein is for the purpose of description and not of limitation. Therefore, while the embodiments herein have been described in terms of preferred embodiments, those skilled in the art will recognize that the embodiments herein can be practiced with modifications. However, all such modifications are deemed to be within the scope of the claims.

What is claimed is:

1. A system for generating and regulating local magnetic field variations for spin qubit manipulation using scalable quantum processors and micro-structures in integrated circuits comprising:
a. a circuit configured to provide an adaptive and independent magnetic-field control to each qubit on a hardware substrate;
b. a plurality of micro/nano-scale current carrying structures of the circuit located in the vicinity of a qubit for controlling and manipulating the qubit using locally generated variable magnetic-field, and wherein the variable magnetic-field is in-turn controlled by the tunable current flowing through the plurality of micro/nano-scale current carrying structures; and
c. a fast current control in conjunction with the plurality of micro/nano-scale current carrying structures is configured to provide fast switching/tuning of magnetic fields enabling rapid adiabatic passage control or tunability of one or more qubits simultaneously; and
wherein the plurality of micro/nano-scale current carrying structures comprises single current carrying loop or multiple current carrying loop, and wherein the tunability of the one or more qubits allows post-fabrication setting of adaptive magnetic field strengths and frequency separation of the one or more qubits, wherein the circuit is configured to support both electron spin resonance (ESR) and electric dipole spin resonance (EDSR) control techniques as per algorithmic requirements and hybrid switching schemes to turn the local magnetic fields off and on as per the requirements; and wherein the ESR involves a microwave line that carries modulated current signals which encode operation information for each qubit at their designated Larmor frequency, and wherein the EDSR involves directly pulsing the gates of the transistors with a similarly modulated voltage signal, and wherein the plurality of micro/nano-scale current carrying structures comprises vertical orientation of loop or horizontal orientation of loop or a combination of both, and wherein the vertical orientation or horizontal orientation of the loop or a combination of both allows flexible control of local magnetic field or generation of a local magnetic field gradient for the qubits, forming a vector magnet.

2. The system according to claim 1, wherein the adaptive magnetic field strengths and frequency separation of the one or more qubits enables the one or more qubits to simultaneously realize their intended control signals without any added disturbance from neighbouring one or more qubits.

3. The system according to claim 1, wherein the hardware substrate is a silicon substrate.

4. The system according to claim 1, wherein the rapid adiabatic passage control or tunability and simultaneous control of the one or more qubits enables integration of millions of one or more qubits and lower overall power consumption, and wherein the integration of millions of one or more qubits is due to multiplex hardware ability of the one or more qubits.

5. The system according to claim 1, wherein the plurality of micro/nano-scale current carrying structures comprises superconducting or normal metal structures, and wherein the superconducting or normal metal structures are selected based on the requirements of the local magnetic field strength and the operational temperature of the qubits.

6. The system according to claim 5, wherein the superconducting micro/nano-scale current carrying structures are used during lower temperature with higher magnetic field densities.

7. The system according to claim 1, wherein the plurality of micro/nano-scale current carrying structures comprises superconducting or normal metal loops split into two or more loops.

8. The system according to claim 1, wherein the qubit is semiconductor-based spin qubit, and wherein the qubit is any system with two different well-defined quantum-mechanical levels.

9. The system according to claim 8, wherein the semiconductor-based spin qubit comprises complementary metal oxide semiconductor (CMOS), and wherein the CMOS involves electrons moving through transistors fabricated in complementary metal oxide semiconductor (CMOS) technology under proper temperature and biasing conditions.

10. A method of co-integrating multiple qubit structures with local magnetic field generating microstructures for defining multiple qubit operating frequencies spin qubits, the method comprising the steps of:
a. generating user-controlled local magnetic field in integrated circuits for multiple qubit structures by means of plurality of micro/nano-scale current-carrying structures;
b. generating user-defined magnetic field direction with varying placement and orientation of plurality of micro/nano-scale current-carrying structures forming a vector magnet; and
c. applying well defined magnetic fields to the multiple qubit structures by varying the current levels and the number of turns associated with the plurality of micro/nano-scale current-carrying structure loops;
wherein the orientation of the plurality of micro/nano-scale current carrying structures comprises vertical orientation of current carrying loop or horizontal orientation of current carrying loop or a combination of both; and wherein the vertical orientation or horizontal orientation of the current carrying loop or a combination of both allows flexible control of local magnetic field or generation of a local magnetic field gradient for the qubit structures, forming a vector magnet.

11. The method according to claim 10, wherein the placement of the plurality of micro/nano-scale current carrying structures comprises 2D/3D structures of different geometrical shapes and not squares alone as permitted by fabrication facilities.

12. The method according to claim 10, wherein the combination of both comprising vertical and horizontal orientation of current carrying loop forms an arbitrary magnetic field direction for the local magnetic field variations in essence forming a vector magnet; and wherein the field strength and the direction of the vector magnet is controlled by the user.

13. The method according to claim 10, wherein the plurality of micro/nano-scale current carrying structures are placed in-plane of the multiple qubit structures instead of vertical orientation during fabrication process to generate required magnetic field.

14. The method according to claim 10, wherein the plurality of micro/nano-scale current carrying structures comprises single current carrying loop or multiple current carrying loop.

15. The method according to claim 10, wherein the multiple qubit structures is placed around a single current carrying loop at different locations allowing to make use of the different magnetic field orientations and strengths surrounding the single current carrying loop; and wherein the multiple qubit structures placed around the single current carrying loop makes use of the existing gradients of the single current carrying loop to reduce the required hardware for generating well-defined local magnetic fields per qubit structure.
